(19) United States
(12) Patent Application Publication
(10) Pub. No.: US 2012/0169350 A1
(43) Pub. Date: Jul. 5, 2012

(54) TEST ACTUATOR FOR TAP CHANGER

(76) Inventor: Alfred Bieringer, Geiselhoering (DE)

(21) Appl. No.: 13/386,594

(22) PCT Filed: Jul. 8, 2010
(86) PCT No.: PCT/EP2010/004166

§ 371 Date: Jan. 31, 2012

(30) Foreign Application Priority Data
Sep. 8, 2009 (DE) 20 2009 012 198.4

(51) Int. Cl. G01R 31/06

(52) U.S. Cl. 324/547

(57) ABSTRACT

The invention relates to a testing drive for examining a stepping switch or a tap changer as part of transformer tests, wherein the testing drive has a servomotor that acts on an adapter by means of a gear train, wherein the adapter can be connected to the upper gear stage of the stepping switch or tap changer during the tests.

The invention relates to a test actuator for checking an on-load tap changer or an off-load tap changer within the scope of tests of the transformer to be regulated.

On-load tap changers serve for uninterrupted switching over between winding taps of a tapped transformer. They have been known for many years in numerous forms of embodiment, for example from the company publication of the applicant ‘VACUTAP® VRLaststufenschalter für Regeltransformatoren’, printing IN206/09de-0708/1000.

The on-load tap changer described there consists of an on-load changeover switch, which is accommodated in a separate oil vessel, and a selector arranged thereunder. The selector serves for power-free preselection of the new winding tap of the tapped transformer which is to be switched over to; the on-load changeover switch serves for the subsequent rapid uninterrupted actual switching over from the previous to the new winding tap.

The entire on-load tap changer is actuated by a motor drive for the switching over. A rotating drive shaft continuously moves the selector and at the same time a force store of the on-load changeover switch is drawn up. When it is completely drawn up, i.e. stressed, it is unlatched, abruptly releases its energy and rapidly actuates, i.e. in the millisecond region, the on-load changeover switch.

The on-load changeover switch can differ depending on the transformer layout with which it is to be connected, the circuit employed as well as other apparatus specifics. In the described on-load changeover switching the on-load changeover switch executes a specific switching sequence, i.e. different mechanical contacts and/or also vacuum switching tubes are actuated in a specific sequence in time in succession or to overlap.

For that purpose, provided at the upper region of the on-load tap changer, at the cover, is a top transmission stage which in the mounted state of the on-load tap changer is coupled with a drive shaft of a motor drive usually fastened laterally to the outer wall of the transformer.

By contrast thereto off-load tap changers serve the purpose of load-free switching over between winding taps of a tapped transformer to be switched off. They are similarly known in numerous forms of embodiment, for example from the company publication of the applicant ‘DEETAP® DU-Umsteller’, printing IN277/01de-0705/500.

Off-load tap changers similarly have at the upper region thereof a cover at which a top transmission stage is similarly provided, which in the mounted state of the off-load tap changer is coupled with a drive shaft of the motor drive or in many cases here also a manual drive.

Before placing the on-load tap changer or off-load tap changer in operation and switching on the tapped transformer numerous checks and measurements, for example resistance and transmission measurements, are required, which are inconvenient particularly because the on-load tap changer of off-load tap changer is still not connected with the motor drive or the manual drive which later actuates it.

The object of the invention is to indicate a test actuator of the kind stated in the introduction by which individual switching actions, movement up to a predetermined position or also a defined complete test cycle can be performed at the separate on-load tap changer or offload tap changer. In that case, the device according to the invention shall be universally usable, i.e. adaptable without substantial effort to on-load tap changers or off-load tap changers of the most diverse modes of construction, particularly different numbers of possible tap settings, with different technical data, etc.

This object is fulfilled by the invention. The parallel patent claims 1 and 2 relate to test actuators of the kind stated in the introduction; the subclaims relate to advantageous developments.

The general inventive idea consists in that a test actuator comprises a servomotor which acts by way of a transmission on an adapter which is periodically connectable with the top transmission stage of an on-load tap changer or off-load tap changer, wherein the test actuator comprises a control unit. In that case data specific to the on-load tap changer or offload tap changer are called up and processed by the control unit.

Such changer-specific data are, in particular: —

adjustment setting

rotational direction for higher/lower

number of revolutions/switching of the transmission stage

switch type

serial number

number of settings and setting ranges

reversal value

maximum permissible torque limit values.

In a first form of realization of this general inventive idea according to patent claim 1 an RFID antenna co-operating with an RFID tag, on which the changer-specific data are stored in non-volatile manner, at the on-load tap changer or off-load tap changer is provided at the test actuator.

In this form of realization an additional equipping, which, however, is not problematic, of the respective on-load tap changer or off-load tap changer with an RFID tag at or on the top cover is accordingly necessary. RFIDs have become established components which are small and are available economically. Here the respective RFID serves the purpose of storing all data specific to the on-load tap changer and keeping the data available for parameterizing.

Alternatively possible within the scope of the invention instead of an RFID are, in principle, also bar codes or the like which, however, have disadvantages in different instances of use, such as, for example, possible soiling and consequently poor readability. Moreover, the information density of such bar codes is less.

In a second form of realization of this general inventive idea according to patent claim 2 the changer-specific data are, thereagainst, stored in non-volatile manner in the control unit itself or in storage media co-operating therewith. Such storage media can be, for example, CDs or USB sticks. It is also possible to store a concordance list of the changer-specific data belonging to the respective serial numbers issued by the manufacturer.

According to an advantageous development of the invention the control unit can also comprise means for manual input of the changer-specific data, for example, if the RFID tag is missing or the storage medium is defective.

The invention shall be explained in more detail in the following by way of figures, in which:

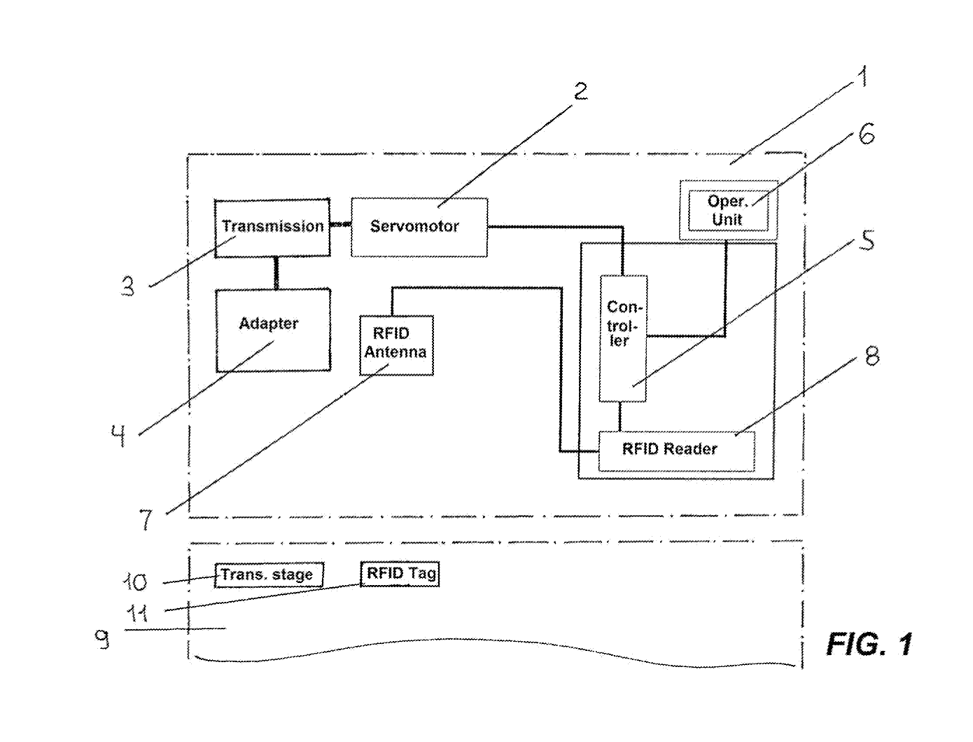

FIG. 1 shows a test actuator according to the invention, here at a on-load tap changer, in schematic illustration and

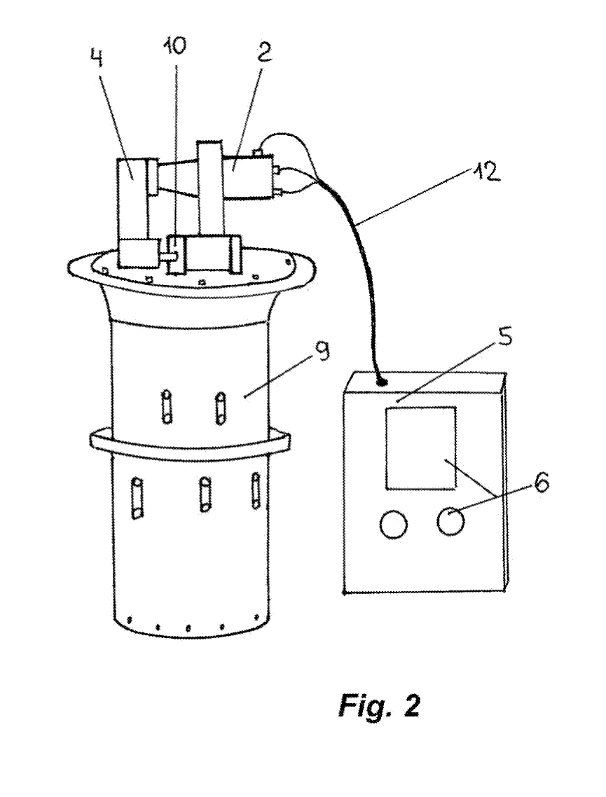

FIG. 2 shows an example of a test actuator of that kind actually mounted at an on-load tap changer.

Initially, the basic construction of a novel test actuator shall be explained in more detail by way of the illustration in FIG. 1. The entire test actuator 1 is here enclosed by a symbolic dashed line. It comprises a servomotor 2 which acts by way of a transmission 3 on an adapter 4. In addition, the test actuator comprises a control unit 5 which co-operates with an operating unit 6. Moreover, an RFID antenna 7 is provided, which is similarly connected with the control unit 5 by way of an RFID reader 8. Shown below the test actuator 1 is in addition—similarly schematically—the upper part of an on-load tap changer 9. Indicated there is a top transmission stage 10 with which the adapter 4 mentioned further above can be connected. Moreover, the similarly mentioned RFID tag 11 is shown, which carries items of information about the data specific to the tap changer and can be read out from the RFID antenna 7.

In the mounted state of the test actuator 1 thus the adapter 4 thereof co-operates with the top transmission stage 10 of the on-load tap changer and the RFID antenna 7 thereof contactlessly with the RFID 11 of the on-load tap changer.

The servomotor 2 with transmission 3, adapter 4 and RFID antenna 7 can, with particular advantage, be adapted in simple manner as an integrated complete unit to the top transmission stage 10 of the on-load tap changer. Through a design of the adapter 4 for mechanically positive connection it is possible to apply to the top transmission stage 10 the torque required there.

As soon as the RFID tag 11 comes into the reading range of the RFID antenna 7 the parameterizing data, i.e. specific on-load tap changer data, are read out by way of the RFID reader 8 and transmitted to the control unit 5. The selected data such as, for example, type number and serial number are indicated at the operating unit 6, which in particularly advantageous manner is constructed as a touch panel.

Subsequently, the adjustment setting has to be confirmed.

A first test switching in order to clearly determine the switching direction of the respective on-load tap changer in the sense of ‘higher’ or ‘lower’ is then carried out.

The test device is then ready for use. Individual switching actions or movement to a specific destination can now be carried out. It is equally possible to allow a predefined test cycle to elapse.

Thus, all required measurements and tests at the respective on-load tap changer or offload tap changer, particularly also all resistance and transmission measurements, are thus possible in simple manner in co-operation with the respective tapped transformer.

FIG. 2 shows an actual arrangement of a test actuator according to the invention at an on-load tap changer 9. The servomotor 2, adapter 4, which co-operates with the top transmission stage 10 of the on-load tap changer 9, and on the right the control unit 5 in a switch cabinet can be seen. Also shown here is a connecting line 12 from the control unit 5 to the servomotor 2.

It is also possible within the scope of the invention to expand the test actuator to three columns in order to enable, with one construction, simultaneous switching of three on-load tap changers and thus to ensure a rational testing of the transformer.

Moreover, it is possible to assess or evaluate a plot of the torque of the corresponding on-load tap changer actuation over time either directly in the control unit 5 or by an additional torque detection. A comparison with a previously determined ‘fingerprint’ of the respective on-load tap changer at the preceding product check at the manufacturer is thus possible. Faults due to distortions or incorrect installations can thereby be detected and eliminated before placing in operation. This is also possible with off-load tap changers. The torque plot can in that case be measured directly or also calculated from the power consumption of the servomotor 2.

For this purpose it is useful if the relevant values of the respective ‘fingerprint’ after product checking are stored on the RFID tag 11 of the on-load tap changer or the storage medium of the control unit 5 so that they are available later for a comparison.

Moreover, it is possible to develop the test actuator according to the invention as a complete system for automated resistance and transmission measurement for transformers with on-load tap changers. These expanded possibilities are equally capable of realization for offload tap changers.

Finally, it is possible within the scope of the invention to provide at the control unit 5 additional control inputs for integration in existing control devices or possibly for remote control.

1-10. (canceled)

11. A test actuator for checking an on-load tap changer or an off-load tap changer within the scope of tests of the associated transformer to be regulated, the test actuator comprising:
an electric motor that is periodically connectable with the on-load tap changer or off-load tap changer;
a control unit co-operating with an operating unit, the electric motor being a servomotor mechanically connected with an adapter by way of a transmission, the adapter being mechanically positively connectable with a top transmission stage of the on-load tap changer or off-load tap changer, and
an RFID antenna co-operating with an RFID tag on the on-load tap changer or off-load on-load tap changer, on which tag the changer-specific data are stored in non-volatile manner in such a manner that these data can be read out in the RFID antenna and the RFID antenna is similarly electrically connected with the control unit by way of an RFID reader.

12. The test actuator defined in claim 11, wherein the servomotor, transmission, adapter and RFID antenna are adaptable as an integrated complete unit to the top transmission stage of the on-load tap changer or off-load tap changer.

13. The test actuator defined in claim 11, wherein three identical test actuators are provided in such a manner that a simultaneous testing of three on-load tap changers or off-load tap changers is possible.

14. The test actuator defined in claim 11, further comprising:
additional means for detecting the torque plot during switching-over.

15. The test actuator defined in claim 14, further comprising:
additional means for comparison of the detected torque plot during the switching over with a specific target value that was stored in non-volatile manner beforehand, of the respective on-load tap changer or off-load tap changer.
